(19) United States
(12) Patent Application Publication
(10) Pub. No.: US 2015/0026016 A1
(43) Pub. Date: Jan. 22, 2015

(54) SYSTEM AND METHOD OF PRODUCING MODEL FIGURE OF PERSON WITH ASSOCIATED CLOTHING

(71) Applicant: Delicious Ltd., New York, NY (US)

(72) Inventor: Gerry DeVeaux, London (GB)

(21) Appl. No.: 13/946,095

(22) Filed: Jul. 19, 2013

(51) Int. Cl. G06Q 30/06; G06T 11/60; H01L 23/48

(52) U.S. Cl. CPC G06Q 30/0643; H01L 23/481; G06T 11/60
USPC 705/27.2

(57) ABSTRACT

A system and method for manipulating models and avatars in a virtual and real Environment is disclosed. The system allows the user to create a virtual image of a model by selecting an avatar and changing different types of features or clothes of the avatar. Users can allocate votes for the virtual image created by others. The best and most preferred design of clothes is selected which can be then generated or produced as a real tangible item and tested on a doll. Also the user with most votes wins virtual currency which can result in prices or additional rewards in the virtual environment as well as the real tangible versions of the model (doll). The tangible doll is produced via defined measurements and most preferably in a doll sized statue or doll as such.

### TECHNICAL FIELD

The present disclosure is concerned with systems and methods of producing model figures of persons with associated clothing. Embodiments of the disclosure are generally related to online virtual dressing game and models and avatars in a virtual and real environment. Moreover, the disclosure is also concerned with computer readable program products or software products which include instructions executable upon computing hardware for implementing aforesaid methods.

### BACKGROUND

Modern life has associated therewith enhanced connectivity that allows for a greater level of accessibility to information and goods, irrespective of time and location. Moreover, such connectivity has resulted in a reduced time required for designing, producing products and services, and subsequent processes of launching such products and services in, for example, stores. Furthermore, the Internet with online purchasing functionality allows for a greater level of immediacy from manufacturing to selling of product and services.

Virtual worlds are blurring a distinction between online and offline retail experiences, by embracing benefits of immediacy and accessibility in a way that are as enjoyable as shopping in “bricks and mortar” shopping environments. Such trends pertain to all types of goods and services, and have also become pertinent to the world of luxury retail brands.

Buying clothing online is notoriously difficult and, as a consequence, many people avoid doing so. Typically, someone buying clothing in a bricks and mortar environment would try on the garment in a changing room, in order to determine whether or not the garment were a satisfactory fit. Replicating such functionality of try on garments in an online environment presents a technological challenge. Many systems for virtual testing and design of clothing have been tried, but have never really been accepted by end customers with full satisfaction.

Retailers have an additional challenge of creating clothes twelve months prior to their release to market. It can be hard to predict, whether or not the garments they design and manufacture will be in demand. In an online environment, it is very difficult to bridge the user experience, and yet technologically provide a link between the virtual experience and a corresponding related tangible product. For luxury brands, the difficulty of replicating a luxury experience in an online environment is also a technical challenge, so such luxury brands still rely on established shows and cat walks to present new designs and to show how they would look on leading models and celebrities. In an effort to increase online sales, retailers have offered ‘money back guarantees’ and swift return policies in order to try to address aforementioned technical challenges.

A customized item that is usable on both a website as an item in a virtual world, and also outside the website as a tangible item in the real world is provided and described in U.S. Pat. No. 8,255,807, the contents of which are incorporated wherein by reference. By invoking an online virtual dressing game, a user can create different designs and then be allocated a code or password for the created design. The code or password is then usable on a second website to purchase the design implemented as an actual tangible item produced on the first website. Online dress-up portal “Stardoll” has been very successful and is leading the way in how girls interact with online dress-up.

### SUMMARY

The following summary is provided to facilitate an understanding of some of the innovative features unique to the disclosed embodiment and is not intended to be a full description. A full appreciation of the various aspects of the embodiments disclosed herein can be gained by taking into consideration the entire specification, claims, drawings, and abstract as a whole.

It is, therefore, one aim of the disclosed embodiments to provide for an online virtual dressing game.

It is another aim of the disclosed embodiments to provide for a system and method of manipulating models and avatars in a virtual and real environment.

It is yet another aim of the disclosed embodiments to optionally provide for a system and method that enables users to change online via the User Interface (UI), all different types of features or clothes of an avatar, for example skin color, hair style, eyes, body type, facial features, clothes, colors, textures, jewelry and even select celebrities or models to test out designed collections or creations.

It is a yet another aim of the present disclosure to optionally provide a fabrication apparatus that manufacture a tangible reproduction of at least one data set, representing a design, in a form of a model figure as an outwardly-viewable image layer backed by one or more support layers.

Optionally, It is a yet another aim of the present disclosure to provide to a system and method that provide, via the User Interface (UI), a competitive game environment in which a user is able to present his or her virtual image of a figure of a person with associated adjustments defined by the user via the User Interface (UI). Moreover, one or more other users are beneficially able to allocate votes for the presented virtual image during execution of the competitive game.

Optionally, it is a yet another aim of the present disclosure to provide a system and method, that award one or more virtual currency prizes as a function of votes obtained for a user's virtual image of a figure of a person with associated adjustments input by the user via a User Interface (UI). Moreover, the one or more virtual currency prizes are beneficially usable at other communication network sites for obtaining other products and/or services.

The aforementioned aims, aspects and other objectives and advantages can now be achieved as described herein. An online virtual dressing game is disclosed. Optionally, the user is provided with an opportunity to create a virtual image of a model by selecting an avatar and changing different types of features or clothes of the avatar. Optionally, Users can allocate votes for the virtual image created by others. Optionally, A best and most preferred design of clothes is selected which can then be generated or produced as a real tangible item and tested on a doll. Moreover, a user gaining most votes wins virtual currency which can result in prizes or additional rewards in the virtual environment as well as the real tangible versions of the model, namely doll. Optionally, A tangible doll is produced via defined measurements and most preferably in a doll-sized statue or doll as such.

### BRIEF DESCRIPTION OF THE DRAWINGS

The summary above, as well as the following detailed description of illustrative embodiments, is better understood when read in conjunction with the appended drawings. For the purpose of illustrating the present disclosure, example constructions of the disclosure are shown in the drawings. However, the disclosure is not limited to specific methods and instrumentalities disclosed herein. Moreover, those in the art will understand that the drawings are not to scale. Wherever possible, like elements have been indicated by like numbers.

FIG. 1 illustrates a simplified block diagram of an example system for manipulating models and avatars in a virtual environment and a real environment, in accordance with the disclosed embodiments;

FIG. 2 illustrates an example User Interface (UI) for entering into a competitive game that manipulates models and avatars in a virtual environment and a real environment, in accordance with the disclosed embodiments;

FIG. 3 illustrates an example UI for selecting hair and makeup styles of a selected model, in accordance with the disclosed embodiments;

FIG. 4 illustrates an example UI showing a boutique selection for a female model, in accordance with the disclosed embodiments;

FIG. 5 illustrates a UI showing a boutique selection for a male model, in accordance with the disclosed embodiments;

FIG. 6 illustrates an example UI showing a created model and its details including votes and prizes, in accordance with the disclosed embodiments;

FIG. 7 illustrates an example UI showing wardrobe items selected by a user, in accordance with the disclosed embodiments;

FIG. 8 illustrates an example UI displaying various models created using the system depicted in FIG. 1 with user name and rank details, in accordance with the disclosed embodiments;

FIG. 8A illustrates an example list of emoticons present on the UI displaying various models created using the system depicted in FIG. 1

FIG. 9 illustrates an example real tangible model created using the system depicted in FIG. 1, in accordance with the disclosed embodiments; and

FIG. 10 illustrates a flow chart pertaining to an example method of manipulating models and avatars in a virtual environment and a real environment, in accordance with the disclosed embodiments.

### DETAILED DESCRIPTION OF ILLUSTRATIVE EMBODIMENTS

The particular values and configurations discussed in these non-limiting examples can be varied and are cited merely to illustrate at least one embodiment and are not intended to limit the scope thereof.

With known systems, the experience of online testing, shopping and designing is very difficult for a given user, and the given user is not effectively shown how a product designed in a virtual environment would appear in real life on different people.

An improved system and method of manipulating models and avatars in a virtual environment and a real environment selects a best and most preferred design of clothes which can then be generated or produced as a real tangible item and tested on models.

The present disclosure provides a system and method of producing a model figure of a person with associated clothing, including using a computer arrangement which is operable to execute one or more computer readable program products or software products to generate a user interface (UI) at which a user is able to manipulate a virtual image of the figure of the person for adjusting at least one of: clothing for the figure, skin color of the figure, facial features of the figure, hair details of the figure, jewelry of the figure; generating at least one data set describing the virtual image of the figure of the person with associated adjustments input by the user via the user interface (UI); and using at least one fabrication apparatus to manufacture a tangible reproduction of the at least one data set in a form of the model figure.

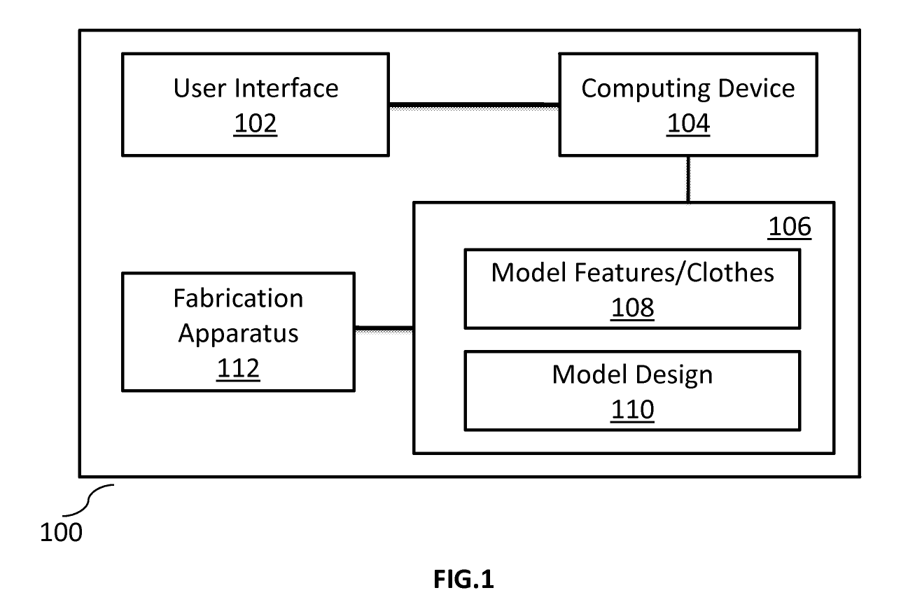

Referring to FIG. 1, a system 100 for producing a model figure of a person with associated clothing is disclosed. The system 100 includes a computing device 104 that is operable to execute one or more computer readable program products or software products, for example one or more non-transitory computer readable program products recorded on machine-readable data storage media, for generating a user interface (UI) 102. The user can manipulate a virtual image of a model or avatar via the UI 102. The system 100 generates one or more data sets describing the virtual image of a model or avatar and stores the sets in a model design database 110. Fabrication apparatus 112 is utilized to manufacture a tangible reproduction of the virtual image in a form of the model. The UI 102 allows the user to adjust model features or clothes such as clothing, skin color, facial features, hair details and jewelry for the model. The various model features and clothes information are stored in a model features and clothes database 108. The model design database 110 and model features and clothes database 108 are together represented as a database 106.

Note that the computing device 104 described above can be deployed as part of a computer network. A server is interconnected via a communications network, for example via a LAN, WAN, intranet or the Internet, with user devices or computing devices. Examples of the computing devices 104 include, but are not limited to: PC, Mac, smart phone, phablets, tablet, mobile telephone, or a wireless PDA (Personal Digital Assistant); these examples function as computing devices. Computing devices 104 can also be any other device that can implement a user interface and/or a browser to communicate with and present content from a server.

The fabrication apparatus 112 optionally utilizes three dimensional (3D) printing for manufacturing the model figure as an outwardly-viewable image layer backed by one or more support layers. Laser-cutting of sheet material can be utilized for forming a peripheral profile of the one or more support layers. Note that the tangible doll can be produced via defined measurements and most preferably in a doll-sized statue or doll. The material may vary from different types of polymers, wood, glass and even semi-precious or precious stones without limitation. Also the doll may be produced using digital fabrication methods such as three dimensional (3D) printing or molding without limitation. The designs are optionally of an adhesive nature, thereby allowing them to be changed or reused at other occasions in “Post-it” style functionality; “Post-it” is a registered trademark of 3M Corporation.

Additional, it should also be noted that the models, namely dolls, may be fabricated from a clear Perspex material and in the size in a range of 10 cm to 25 cm in height, in a range of 3 cm to 8 cm in width, and in a range of 2 cm to 3.5 cm in depth. The designs are in two dimensions and can have a front and a back design. The designs can also optionally have two front views which are mirror images of each other to fit the doll and give the best view of the model, irrespective of the viewing direction. Accessories such as hand bags, jewelry, gloves, scarfs and glasses may all be included in the design to make its experience as real and varied as possible.

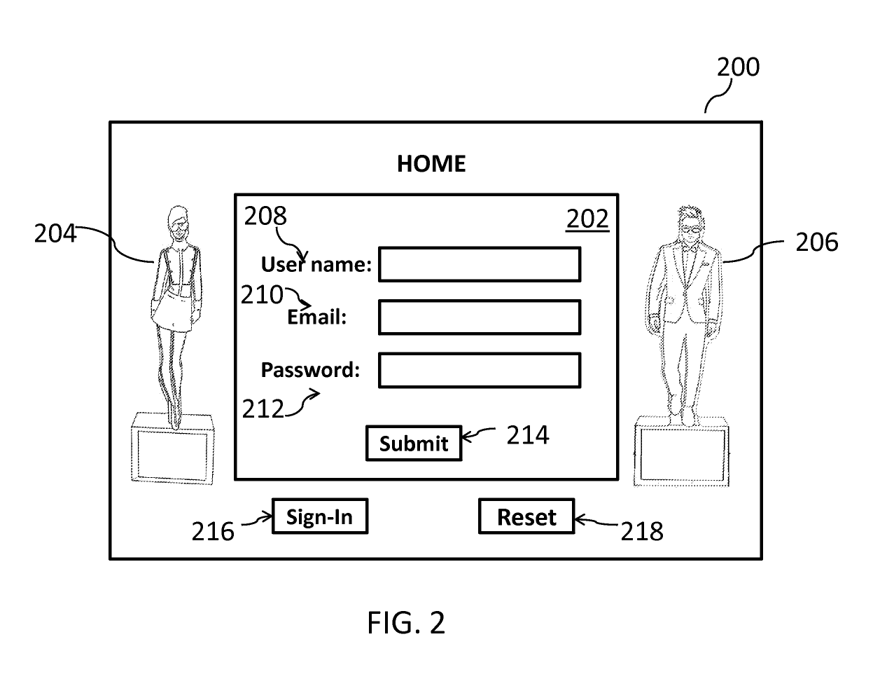

In FIG. 2, there is provided an illustration of a User Interface (UI) 200 for entering into a competitive game that manipulates models and avatars in a virtual environment and in a real environment. In the UI 200, the user can enter user details 202 such as user name 208, Email 210 and password 212. The UI 200 also allows the user to select a male model 206 or a female model 204 to be designed as a virtual image. After selecting a model and entering the user details 202, the user enters an online virtual dressing game by clicking a “Submit” button 214. The dressing game allows the user to create a virtual image of the model and manipulate models and avatars in a virtual environment and a real environment.

It is to be noted that the UI 200 allows the user to create an account for entering the competitive game. The UI 200 also allows users who already have accounts to sign in by clicking a “Sign in” button 216 and allows resetting their password 212 by clicking a “Reset” button 218. By entering the already given Email 210, the user can reset his or her password.

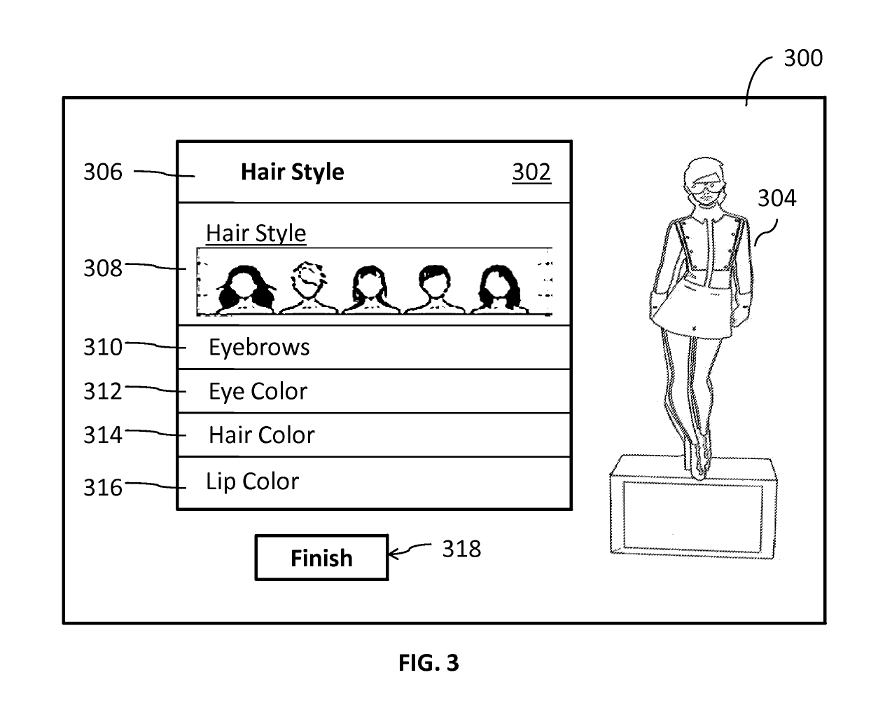

Referring to FIG. 3, a UI 300 for selecting hair and makeup styles 302 of a selected model 304 is disclosed. The user is able to select hair and makeup styles 302 such as hair style 306, eyebrows 310, eye color 312, hair color 314 and lip color 316 for the selected model 304. For example, as shown in FIG. 3, the user is able to select one hair style from various hair styles 308. After selecting the required hair and makeup styles 302, the final model 304 with selected hair and makeup style is displayed and the user is then able to complete the hair and makeup selection by clicking a “Finish” button 318.

The aforesaid online experience allows the user to change all different types of features or clothes of the avatar, for example skin color, hair, eyes, body type, clothes, colors, textures and even select celebrities or models on which to test out the collections or creations designed. Virtual currency prizes are awarded based on votes obtained for the user's virtual image of the figure of the person with associated adjustments input by the user via the UI. The virtual currency prizes are usable at other communication network sites for obtaining other products and/or services.

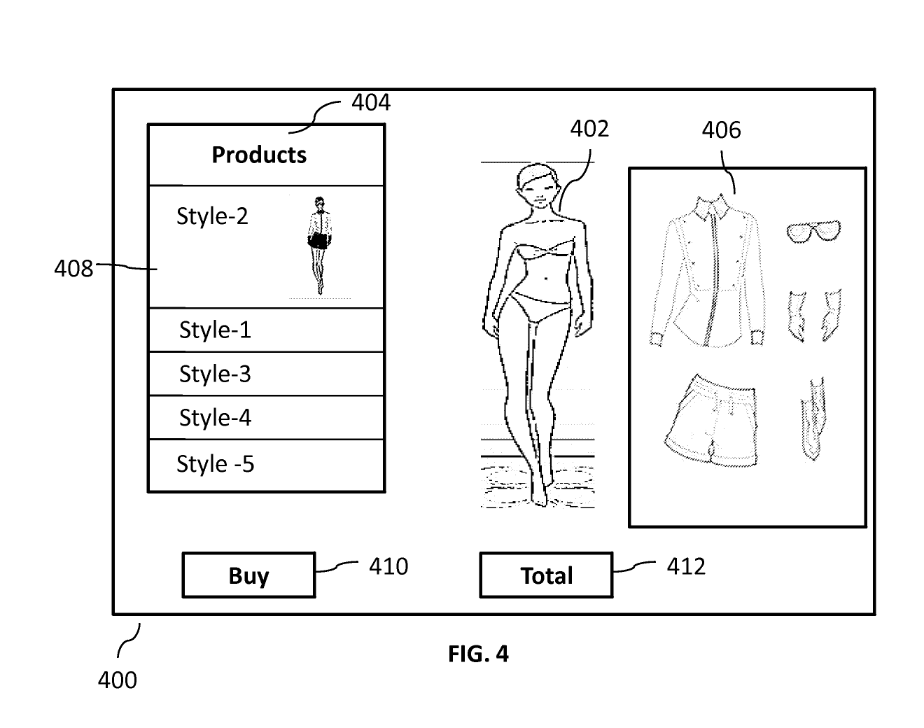

In FIG. 4, there is illustrated a UI 400 showing a boutique selection for a female model 402, in accordance with the disclosed embodiments. The user can shop through a range of luxury brands using a virtual currency and thereafter selects a brand. The list of products in the selected brand is referred to collectively as products 404. For example, the products 404 may include various styles as shown. When the user selects a particular style, the female model 402 wearing the selected style 408 is displayed. The UI 400 also displays a whole outfit 406 of the selected style 408. The user can buy the individual garments or the whole outfit according to their wish by clicking a “Buy” button 410. The user can be informed about his or her total purchase by clicking a “Total” button 412.

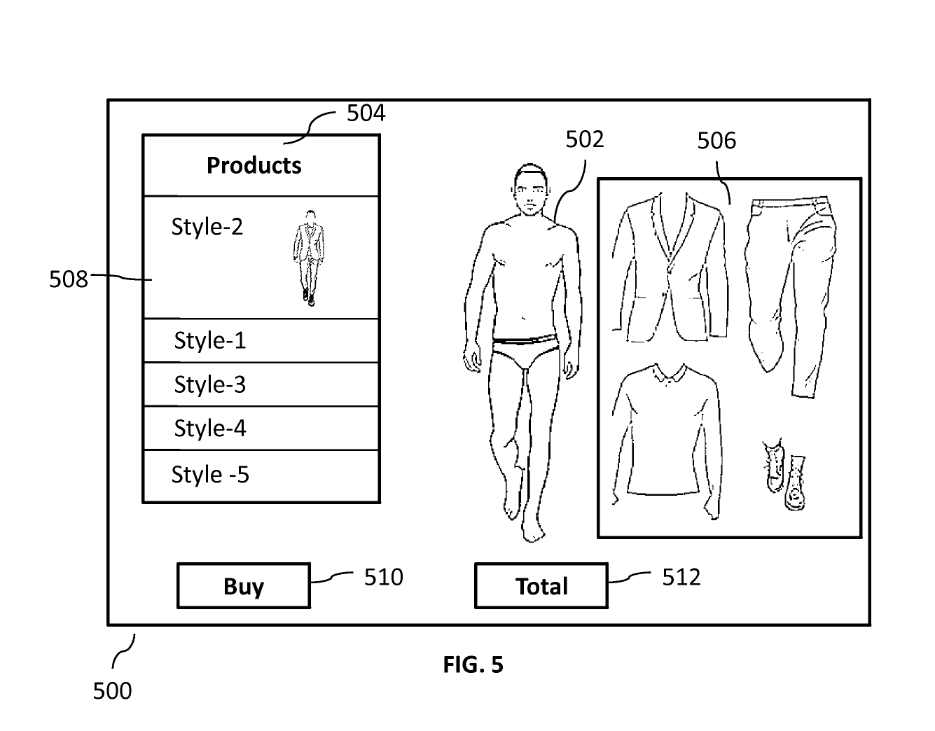

Referring to FIG. 5, a UI 500 showing boutique selections for a male model 502 is disclosed. The user can shop through a range of luxury brands by using a virtual currency and thereafter select a brand. A list of products in the selected brand is referred to collectively as products 504. For example, the products 504 may include various styles as shown. When the user selects a particular style, the male model 502 wearing the selected style 508 is displayed. The UI 500 also displays a whole outfit 506 of the selected style 508. The user can buy the individual garments or the whole outfit according to his or her wish by clicking a “Buy” button 510. The user can learn his or her total purchase by clicking a “Total” button 512.

It is to be noted that the user with most votes for the created model wins virtual currency which can result in prizes or additional rewards in the virtual environment as well as the real tangible versions of the model.

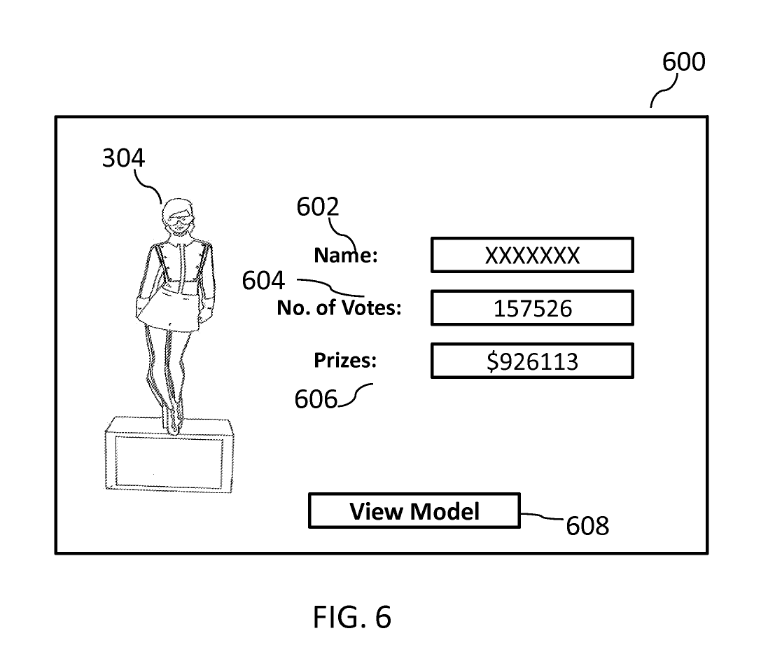

In FIG. 6, there is provided an illustration of a UI 600 showing a created model 304 and its associated details, in accordance with the disclosed embodiments. The details may include a user name 602, a number of votes 604 and total prizes 606 for the created model 304. The user can view other models by clicking a “View Model” button 608.

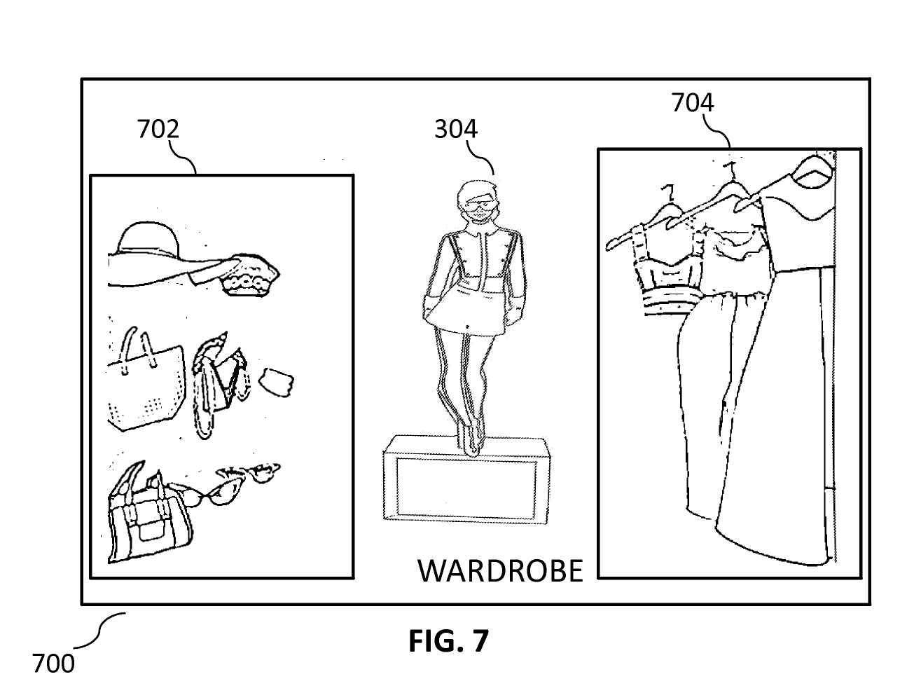

In FIG. 7, there is provided an illustration of a UI 700 showing wardrobe items 702 and 704 selected by a user for the model 304. It is to be noted that the wardrobe items 702 and 704 include items purchased by the user by utilizing the UI's 400 and 500 and also other items purchased by the user while playing one or more games.

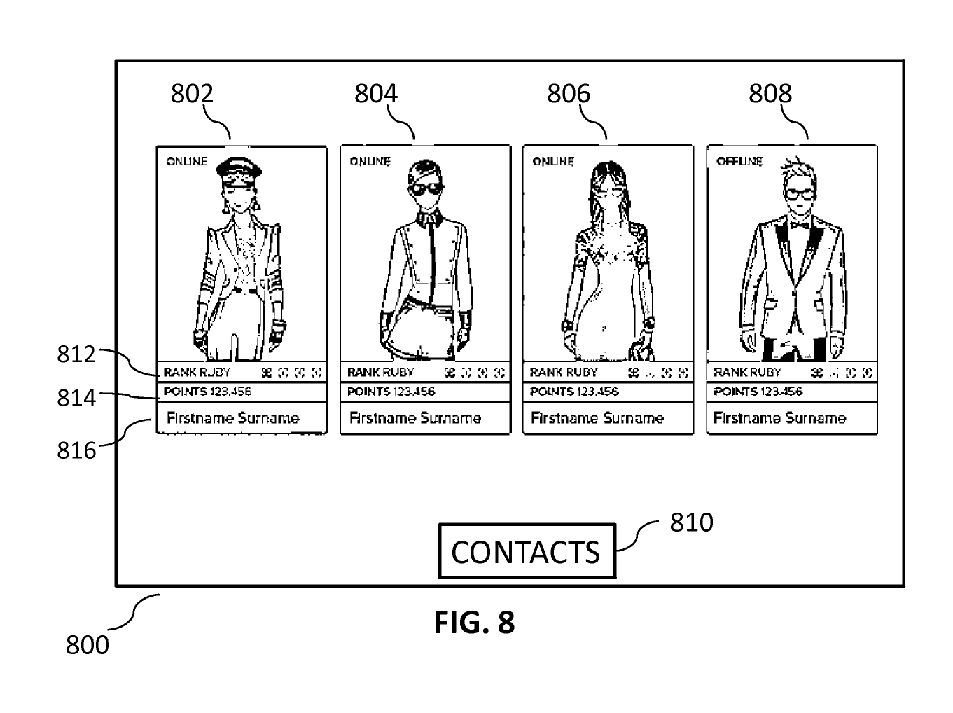

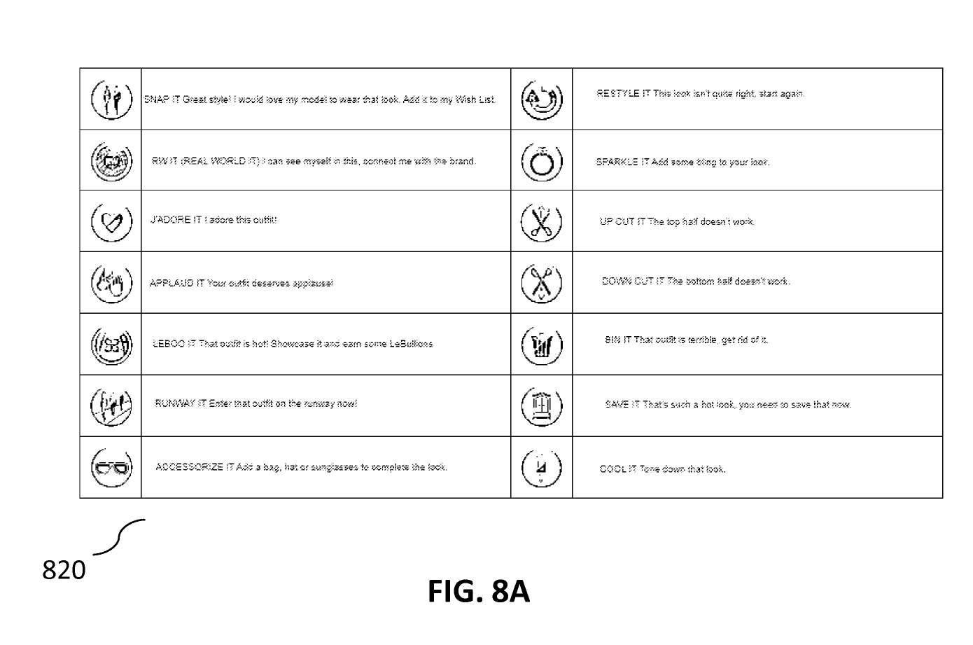

Referring next to FIG. 8, there is provided an illustration of a UI 800 displaying various models 802, 804, 806 and 808 created using the system 100. The UI 800 allows the user to check the status of other users. Moreover, a user name 812, a rank 814 and points 816 for each model in a virtual environment is displayed. The UI 800 also shows availability (online/offline) of other contacts in one or more games. The user may check for more user status by clicking a “Contacts” button 810 as shown.

In FIG. 8A illustrates a list of emoticons 820, also called LeBoo Tags, present on the UI displaying various models created using the system 100. The emoticons 820 also allow for multiplayer selection of the virtual environment of the online User Interface. Users are able to drag ‘LeBoo Tags’ onto the other users creations or models to communicate certain points. For example, a user could drag the heart shaped tag, known as ‘J'Adore It’, which means that they adore the other persons outfit on model. Another example is if a user dragged the ‘Accessorize It’ tag onto the other user, which is to communicate that they should add an accessory to their look.

These emoticons can help users to take many different actions on models created by themselves or others. In a non-limiting example, emoticons for actions are presented in the figure for adding the model in users' wish list, connecting with brand to get the outfit on your model or in real life, adoring the outfit on someone else's or your model, applauding the outfit, showcasing on the platform to earn virtual currency (so called LeBullion), view on a virtual fashion ramp, adding accessories such as bag, glasses on the model, restyling the model, sparkling the outfit, editing the upper half, editing the lower half, deleting, saving, and toning down the look of the created models. There is further a LeBoutique that allows the users to use the LeBullion currency as well as real currency for purchases. Also, a user may also share the model using emoticons with other users in the real or virtual environment of LeBoo. Further the emoticons 820 may be used to share models and outfits on social networking sites such as Facebook, Myspace, Google Plus, Orkut, or other online environments outside the own virtual environment.

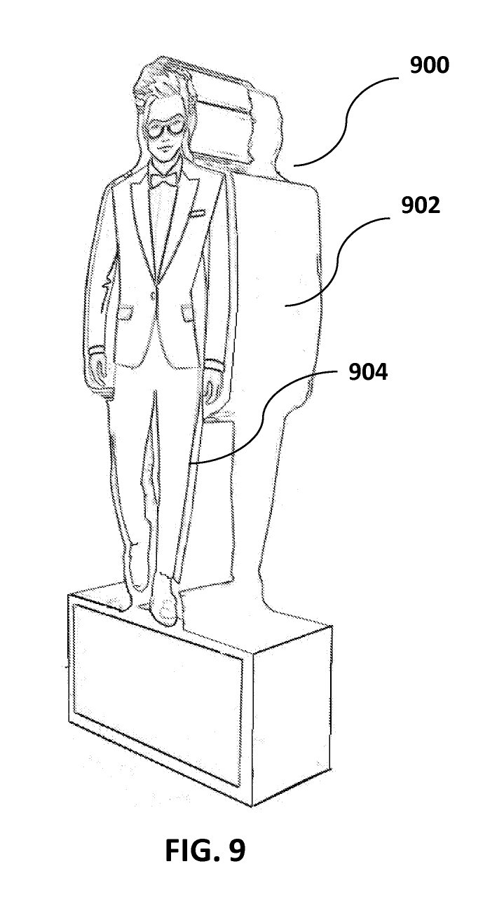

In FIG. 9, there is shown a real tangible model FIG. 900 created using the system 100. The fabrication apparatus 112 is utilized to manufacture the model FIG. 900 as an outwardly-viewable image layer 902 backed by one or more support Layers 904.

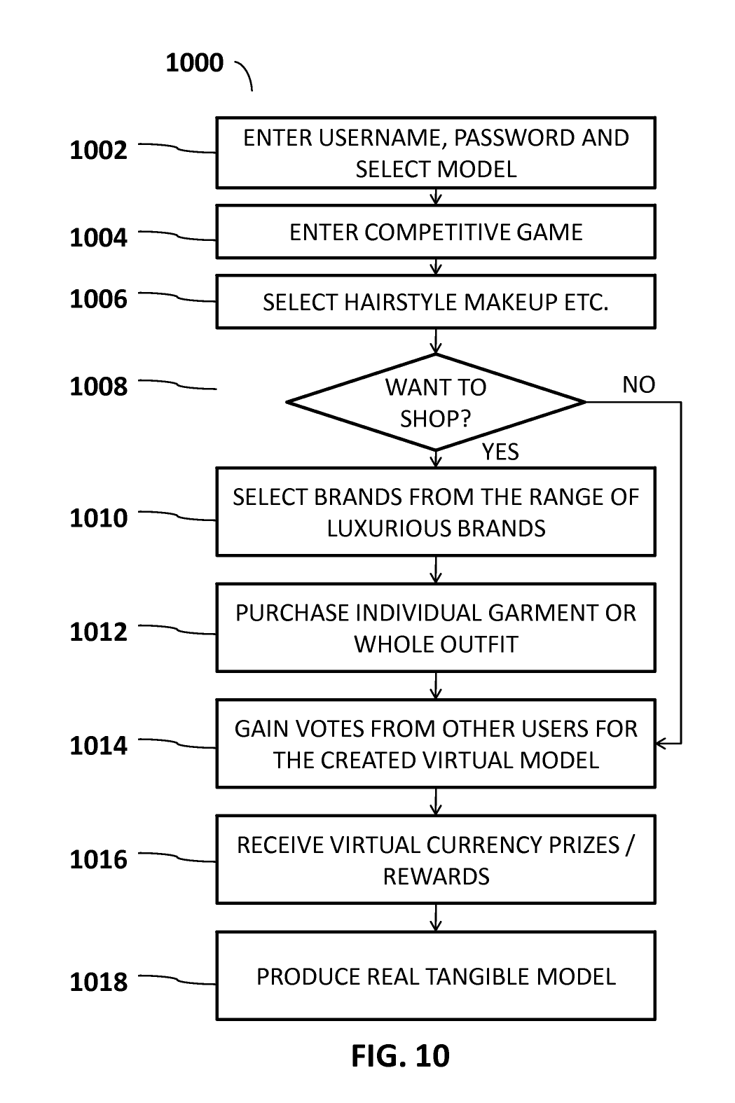

In FIG. 10, there is provided a flow chart 1000 showing steps of a method of manipulating models and avatars in a virtual environment and a real environment, in accordance with the disclosed embodiments. The method is depicted as a collection of steps in a logical flow diagram, which represents a sequence of steps that can be implemented in hardware, software, or a combination thereof. As aforementioned, at a block 1002, the user enters a username and a password and selects a desired model. The user enters a virtual competitive online dressing game for manipulating models and avatars in a virtual environment and a real environment as illustrated at a block 1004. Thereafter, as depicted at a block 1006, the user can select hair and makeup style for the selected model. The hair and makeup style may include hair style, eyebrows, eye color, lip color and hair color for the model.

The user can then select whether or not they wish to buy various products as aforementioned at a block 1008. As depicted at blocks 1010 and 1012, if the user wishes to buy any products, he/she can select a brand from a range of brands of luxurious brands and may purchase individual garments or a whole outfit. The user may gain votes from other users for the created virtual model and a user with most votes wins virtual currency which can result in prizes or additional rewards in the virtual environment as illustrated at blocks 1014 and 1016. Finally, as aforementioned, at a block 1018, the real tangible version of the doll can then be produced via defined measurements and most preferably in a doll-sized statue or doll.

It is to be noted here that the steps followed in the flow chart 1000 are only illustrative and other alternatives can also be provided where one or more steps are added, one or more steps are removed, or one or more steps are provided in a different sequence without departing from the scope of the claims herein.

It will be appreciated that variations of the above disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

Although embodiments of the current disclosure have been described comprehensively, in considerable detail to cover the possible aspects, those skilled in the art would recognize that other versions of the disclosure are also possible.

1. A method of producing a model figure of a person with associated clothing, including:
using a computer arrangement operable to execute one or more computer readable program products to generate a user interface (UI) at which a user is able to manipulate a virtual image of the figure of the person for adjusting at least one of:
clothing for the figure, skin color of the figure, facial features of the figure, hair details of the figure, jewelry of the figure;
generating at least one data set describing the virtual image of the figure of the person with associated adjustments input by the user via the user interface (UI); and
using at least one fabrication apparatus to manufacture a tangible reproduction of the at least one data set in a form of the model figure.

2. A method as claimed in claim 1, further including using the fabrication apparatus to manufacture the model figure as an outwardly-viewable image layer backed by one or more support layers.

3. A method as claimed in claim 2, further including using 3-dimensional printing for manufacturing the outwardly-viewable image layer and/or the one or more support layers.

4. A method as claimed in claim 2, further including using laser-cutting of sheet material for forming a peripheral profile of the one or more support layers.

5. A method as claimed in claim 1, further including employing the user interface to provide a user experience including one or more luxury products associated with the virtual image.

6. A method as claimed in claim 1, further including selecting the virtual image of the figure of the person from one or more databases including a selection of pre-prepared virtual images.

7. A method as claimed in claim 1, wherein the clothing for the virtual image of the figure of the person is user adjustable via the user interface (UI) for customizing one or more features of the clothing.

8. A method as claimed in claim 1, further including providing via the user interface (UI) a competitive game environment in which the user is able to present his/her virtual image of the figure of the person with associated adjustments defined by the user via the user interface (UI), wherein one or more other users are able to allocate votes in respect of the presented virtual image during execution of the competitive game.

9. A method as claimed in claim 8, further including awarding one or more virtual currency prizes as a function of votes obtained for the user's virtual image of the figure of the person with associated adjustments input by the user via the user interface (UI), wherein the one or more virtual currency prizes are usable at other communication network sites for obtaining other products and/or services.

10. A method as claimed in claim 1, further including providing a virtual wardrobe via the user interface (UI) including the clothing selected by the user, wherein the virtual wardrobe is storable on a database for later use.

11. A system for producing a model figure of a person with associated clothing, including:
a computer arrangement which is operable to execute one or more computer readable program products for generating a user interface (UI) at which a user is able to manipulate a virtual image of the figure of the person for adjusting at least one of: clothing for the figure, skin color of the figure, facial features of the figure, hair details of the figure;
an input arrangement coupled to the computer arrangement for enabling the user to generate at least one data set describing the virtual image of the figure of the person with associated adjustments input by the user via the user interface (UI); and
at least one fabrication apparatus for manufacturing a tangible reproduction of the at least one data set in a form of the model figure.

12. A system as claimed in claim 11, wherein the fabrication apparatus is operable to manufacture the model figure as an outwardly-viewable image layer backed by one or more support layers.

13. A system as claimed in claim 12, wherein the fabrication apparatus is operable to employ 3-dimensional printing for manufacturing the outwardly-viewable image layer and/or the one or more support layers.

14. A system as claimed in claim 12, wherein the fabrication apparatus is operable to employ laser-cutting of sheet material for forming a peripheral profile of the one or more support layers.

15. A system as claimed in claim 11, wherein the user interface is operable to provide a user experience including one or more luxury products associated with the virtual image.

16. A system as claimed in claim 11, wherein the system is operable to enable the user to select the virtual image of the figure of the person from one or more databases including a selection of pre-prepared virtual images.

17. A system as claimed in claim 11, wherein the system is operable to enable the clothing for the virtual image of the figure of the person to be user adjustable via the user interface (UI) for customizing one or more features of the clothing.

18. A system as claimed in claim 11, wherein the system is operable to provide via the user interface (UI) a competitive game environment in which the user is able to present his/her virtual image of the figure of the person with associated adjustments defined by the user via the user interface (UI), wherein one or more other users are able to allocate votes in respect of the presented virtual image during execution of the competitive game.

19. A system as claimed in claim 18, wherein the system is operable to award one or more virtual currency prizes as a function of votes obtained for the user's virtual image of the figure of the person with associated adjustments input by the user via the user interface (UI), wherein the one or more virtual currency prizes are usable at other communication network sites for obtaining other products and/or services.

20. A system as claimed in claim 11, wherein the system is operable to provide a virtual wardrobe via the user interface (UI) including the clothing selected by the user, wherein the virtual wardrobe is storable on a database for later use.

21. A computer readable product recorded on non-transitory machine-readable data storage media, comprising instructions executable upon computing hardware for implementing a method as set forth in claim 1.
